(19) United States
(12) Patent Application Publication
(10) Pub. No.: US 2021/0231836 A1
(43) Pub. Date: Jul. 29, 2021

(54) OPTICALLY INDUCED PHASE CHANGE MATERIALS

(71) Applicant: BAE Systems Information and Electronic Systerms Integration Inc., Nashua, NH (US)

(72) Inventors: Don A. Harris, Columbia, MD (US); Pierre-Alain S. Auroux, Rockville, MD (US); Michael J. Bowers, II, Sykesville, MD (US); Myeongseob Kim, Ellicott City, MD (US)

(21) Appl. No.: 16/636,376

(22) PCT Filed: Feb. 28, 2019
(86) PCT No.: PCT/US19/19969

§ 371 Date: Feb. 4, 2020

(51) Int. Cl. G02B 1/00; G02F 1/19; H01L 45/00

(52) U.S. Cl. CPC G02B 1/002; G02F 1/19; G02F 2202/30; H01L 45/1286; H01L 45/14

(57) ABSTRACT

The system and method for a metal meta-material embedded with a phase change material to form an optically induced phase change material. A metal doped polymer domain within the optically induced phase change material provides electric-field enhancement at the interface with a semiconductor domain and provides a thermal heat sink, to provide rapid thermal dissipation away from the semiconductor domain during the optical process.

### FIELD OF THE DISCLOSURE

The present disclosure relates to phase change materials, and more particularly to optically induced phase change materials used in applications requiring ultrafast response times and strong, non-perturbative responses.

### BACKGROUND OF THE DISCLOSURE

Current phase change materials undergo a thermal phase change. While the response for current phase change materials is strong and non-perturbative, the thermal transition is slow and requires a lot of energy. On the other hand, nonlinear optical materials undergo electronic transitions, which may be fast, but they tend to be weak (perturbative). Wherefore it is an object of the present disclosure to overcome the above-mentioned shortcomings and drawbacks associated with conventional phase change materials, by detailing an artificial material which takes the best of both conventional phase change materials and nonlinear optical material. This material has a strong, non-perturbative response, with a fast reaction time and only requires a minimum amount of energy to induce.

### SUMMARY OF THE DISCLOSURE

One aspect of the present disclosure is an optically induced phase change material, comprising: a block co-polymer structure as a meta-material scaffold having different classes of nanoparticles segregated and embedded in different domains, wherein the domains comprise: a metal doped polymer domain; and a phase change domain interface; the metal doped polymer domain providing electric-field enhancement at an interface with the phase change domain, and providing a thermal heat sink for rapid thermal dissipation away from the phase change domain during an optical process.

One embodiment of the optically induced phase change material is wherein the metal doped polymer domain comprises a metal is any class of nanoparticles which allow for surface passivation with molecular ligands, including gold (Au), Silver (Ag), Copper (Cu), or Aluminum (Al).

Another embodiment of the optically induced phase change material is wherein the phase change domain comprises a chalcogenide based phase change material, a transitional metal oxide, or a conventional optically active semiconductor.

In certain embodiments, the chalcogenide based phase change material contains one or more chalcogen elements. In some cases, the transitional metal oxide is VO₂. In certain cases, the conventional optically active semiconductor is CdSe.

Yet another embodiment of the optically induced phase change material is wherein the optically induced phase change material has an optical threshold of about 10-100 μJ/cm² and a response time of about 10-100 ps.

Still yet another embodiment of the optically induced phase change material is wherein the optical process is an optical limiter, and all-optical switch, an optical integrated circuit element, or a beam deflector.

Another aspect of the present disclosure is a method of protecting an optical detector, comprising: providing an optical limiter, the optical limiter comprising: a block co-polymer structure as a meta-material scaffold having different classes of nanoparticles segregated and embedded in different domains, wherein the domains comprise: a metal doped polymer domain; and a phase change domain interface; the metal doped polymer domain providing electric-field enhancement at an interface with the phase change domain, and providing a thermal heat sink for rapid thermal dissipation away from the phase change domain during an optical process; the optical limiter being cast as a polymer film, and applied to a curved surface.

The method of protecting an optical detector according to claim 9, wherein the optical limiter switches to an opaque/reflective state upon irradiation by a laser source above a set threshold, thereby protecting the detector and/or an operator from interrogating radiation.

One embodiment of the method of protecting an optical detector is wherein the metal doped polymer domain comprises a metal is any class of nanoparticles which allow for surface passivation with molecular ligands, including gold (Au), Silver (Ag), Copper (Cu), or Aluminum (Al).

Another embodiment of the method of protecting an optical detector is wherein the phase change domain comprises a chalcogenide based phase change material, a transitional metal oxide, or a conventional optically active semiconductor.

In some cases, the chalcogenide based phase change material contains one or more chalcogen elements. In certain embodiments, the transitional metal oxide is VO₂. In some embodiments, the conventional optically active semiconductor is CdSe.

Yet another embodiment of the method of protecting an optical detector is wherein the optically induced phase change material has an optical threshold of about 10-100 μJ/cm² and a response time of about 10-100 ps.

Yet another aspect of the present disclosure is a method of optical switching, comprising: providing an optical switch, the optical switch, comprising; a block co-polymer structure as a meta-material scaffold having different classes of nanoparticles segregated and embedded in different domains, wherein the domains comprise: a metal doped polymer domain; and a phase change domain interface; the metal doped polymer domain providing electric-field enhancement at an interface with the phase change domain, and providing a thermal heat sink for rapid thermal dissipation away from the phase change domain during an optical process; the meta-material having a variable optically induced reflectivity, to be used as a modulator to transfer encoded information onto a light source, or as a light controllable shutter for optical packet routing on a photonic chip.

One embodiment of the method of optical switching is wherein the optically induced phase change material has an optical threshold of about 10-100 μJ/cm² and a response time of about 10-100 ps.

Another embodiment of the method of optical switching is wherein the metal doped polymer domain comprises a metal is any class of nanoparticles which allow for surface passivation with molecular ligands, including gold (Au), Silver (Ag), Copper (Cu), or Aluminum (Al).

Yet another embodiment of the method of optical switching is wherein the phase change domain comprises a chalcogenide based phase change material, a transitional metal oxide, or a conventional optically active semiconductor.

These aspects of the disclosure are not meant to be exclusive and other features, aspects, and advantages of the present disclosure will be readily apparent to those of ordinary skill in the art when read in conjunction with the following description, appended claims, and accompanying drawings.

### BRIEF DESCRIPTION OF THE DRAWINGS

The foregoing and other objects, features, and advantages of the disclosure will be apparent from the following description of particular embodiments of the disclosure, as illustrated in the accompanying drawings in which like reference characters refer to the same parts throughout the different views. The drawings are not necessarily to scale, emphasis instead being placed upon illustrating the principles of the disclosure.

FIG. 1A is a diagram of possible nanoparticle embedded block co-polymer unit cells according to the principles of the present disclosure.

FIG. 1B shows an enlarged portion of one nanoparticle embedded block co-polymer unit cell according to the principles of the present disclosure as shown in FIG. 1A.

FIG. 2A shows one embodiment of the optically induced phase change material of the present disclosure in an ON state in an all optical switch.

FIG. 2B shows one embodiment of the optically induced phase change material of the present disclosure in an OFF state in an all optical switch.

### DETAILED DESCRIPTION OF THE DISCLOSURE

For decades, phase change material (PCM) has been the cornerstone for solid state memory and optical storage applications. These PCMs, typically chalcogenide based alloys, undergo an amorphous to crystalline phase transition whereby the electrical and optical properties experience large non-perturbative transitions between dielectric to metal behavior. While the evidence of the transition is observed optically or electrically, the driving force behind this phase transition is thermal.

One limitation of current PCMs is that the temperature changes typically occur on a relatively slow temporal scale, making them ideal for memory applications, but preclude applications that require a fast phase transition speed, like high-speed optical switching/computing, optical limiters, or the like.

Another limitation of current PCMs is related to the energy threshold required to induce a phase transition. Often, the energy required for a phase transition far exceeds the joule heating available from low optical powers, and therefore must be accessed electrically. The slow temporal scale limitation is not an intrinsic material limitation, but rather is related to the slow cooling of the material.

In one embodiment of the optically induced phase change material of the present disclosure, a metal meta-material is embedded with a phase change material to form an optically induced phase change material. According to one embodiment of the present disclosure, the thermal change for the material occurs very fast by quickly dissipating energy away from the phase change material, to accelerate the phase transition. In certain embodiments, the optically induced phase change meta-material produces a strong, non-perturbative response, with ultrafast response times.

In some embodiments, a metal doped polymer domain within the optically induced phase change material performs two functions. First, the metal doped polymer domain provides electric-field enhancement at the interface with a semiconductor domain within the optically induced phase change material. This effectively lowers the optical threshold for any processes that natively occur in the semiconductor material. Second, the metal doped polymer domain provides a thermal heat sink, to provide rapid thermal dissipation away from the semiconductor domain during the optical process. In certain embodiments, the metal in the metal doped domain is comprised of any class of nanoparticles which allow for surface passivation with molecular ligands. These nanoparticles can be gold (Au), Silver (Ag), Copper (Cu), or Aluminum (Al).

In some embodiments of the present disclosure, the optically induced phase change material is produced via block co-polymer (BCP) directed self-assembly techniques such that the respective polymer domains are doped with metal and semiconductor nanoparticles (NP). A self-consistent model that combines light-matter interactions with nanoscopic thermal transport theory was the foundation for the design tool of the present disclosure which was required to harness the full capabilities of a new class of optical and opto-electrical materials. The materials used are based on nanoscale self-assembled building blocks comprised of block copolymer structures with embedded nanoparticles. By inducing optical phase change behavior in non-phase change materials through a shift from thermal to electronic phenomenology, the response time, threshold and strength were enhanced.

In one embodiment of the system of the present disclosure, the phase change NP is a chalcogenide based phase change material (i.e., GeTe), a transitional metal oxide (i.e. VO₂) or a conventional optically active semiconductor (i.e., CdSe). For the chalcogenide based phase change material an inherent Metal-Insulator transition was used for the phase change behavior. Chalcogenide materials contain one or more chalcogen elements (i.e., group 16 of the periodic table, e.g., S, Se, Te) as a substantial constituent. These are covalently bonded materials and, although they may be amorphous or crystalline, they are fundamentally semiconductors with a band gap typically of about 1-3 eV, depending on their composition.

One embodiment of the present disclosure is a new class of artificial optical material comprised of block co-polymer (BCP) structures as a meta-material scaffold with different classes of nanoparticles (NP) segregated and embedded in different domains (e.g., metal and phase change). BCPs can phase segregate to create ordered nanoscale structures with domain spacing on the order of tens to hundreds of nanometers, thereby creating a sub-wavelength meta-material scaffold for visible and infrared wavelengths. This metamaterial scaffold creates a volume of ultra-high interstitial surface area whereby the metal filled domain acts as a heat sink to dissipate heat, speeding up the phase transition, and the interstitial metal surface provides electric field enhancement for the phase change domain, lowering the optical threshold.

In one embodiment, Mott-Anderson localization/delocalization transitions were engineered in CdSe NPs and metal NPs embedded in alternating BCP domains with spatial order/disorder controlled by solvent vapor annealing (SVA) techniques. SVA are a class of techniques which involve exposing the BCP film to an organic solvent vapor to swell the film, then applying an external force to either induce order or disorder before the solvent evaporates, locking the BCP film morphology. In another embodiment, an ultrafast thermal phase change and a decreased optical threshold were engineered in GeTe NPs and metal NPs embedded in alternating BCP domains with spatial order/disorder controlled by SVA techniques.

Selective nanoparticle (NP) embedded block co-polymer (BCP) assemblies provide controllable sub-wavelength nanoscale control of structure (BCP morphology) and function (NP properties), serving as nascent building blocks. In one embodiment, GeTe NPs were embedded in one domain of a block co-polymer assembly and the domain behaved as a PCM, surrounded by Au NPs embedded in the other BCP domain. Nanoscale thermal transport in Au embedded BCP domains enabled ultrafast thermal phase change in GeTe embedded BCP structures.

In one embodiment, an ultrafast thermal change resulted in switching times of about 10-100 ps, which is an improvement of over three orders of magnitude compared to conventional bulk phase change material films. Nanoscale plasmonic field enhancement in Au embedded BCP structures enabled optical power concentration by a factor of 10³, decreasing the optical threshold of the GeTe embedded BCP structures. In one embodiment, the decreased optical threshold of phase change resulted in a switching energy of about 10-100 μJ/cm², which is an improvement of three orders of magnitude compared to conventional bulk phase change material films.

In certain embodiments, there exists a minimum threshold concentration of metal NPs in the BCP domain volume such that there is electronic coupling to neighboring metal NPs such that to domain begins to exhibit the bulk behavior of the native metal. In certain embodiments, the optically induced phase change material had a response strength that was strong and non-perturbative. In certain cases, the material had an optical threshold of about 10-100 μJ/cm² and a response time of about 10-100 ps. This capability lends itself to enhanced optical limiters; all-optical switches; optical integrated circuit elements; and beam deflectors; just to name a few.

Current optical limiters are absorbers, so they can be damaged by incident radiation. Using optical limiters comprised of the optically induced phase change material of the present disclosure provides for reflective action which is quicker and lasts longer. Here, the action is triggered by a photon and can persist until it is shut off, or there is a thermal cool down of the material. In some cases, the wavelengths used to transition from a transparent state to a reflective state are less than 1 micron.

To induce an ultrafast thermal phase change, a highly thermally conductive material was used to define a maximum active region such that the heat dissipation is completed on an ultrafast time scale. The thermal diffusion time, τ_{d}, is related to the active region, deft, and material thermal diffusivity, D, by the relation₄: τ_{d} ˜(d_{eff})²/D. For gold (D=1.27×10⁻⁴ m²/s). An active region containing a gold “heat sink” with a target size of about 50 nm will therefore dissipate heat with a diffusion time of about 20 ps. However, the gold “heat sink” cannot be diffused, but rather, must have a high surface to volume ratio to provide field enhancement of incident optical radiation, thereby reducing the optical threshold of the PCM contained within the gold “heat sink” structure. This internal morphology also determines how the structure couples with the incident light. For example, a lamellar structure resembles a dielectric stack and can be used to set up standing waves in the material. Classes of gyroid structures have chiral symmetry and can selectively couple circularly polarized light. In addition, a cylindrical structure can couple linearly polarized light.

The three criteria for the building blocks of the present disclosure were: 1) controlled spatial order/disorder, 2) metal containing unit cells on the order of 50 nm, and 3) non-diffuse internal structure/morphology within the unit cell which allowed for field enhancement from contiguous metal surfaces. To fulfill these material requirements, BCPs that self-assemble on a nanometer scale (10-100 nm unit cells) with morphology parameters and spatial order being primarily controlled by the volume fractions and molecular weights of the constituent blocks were used, with additional tunability offered through a number of different annealing (post-processing) techniques.

In some embodiments, NPs can be selectively added to distinct copolymer domains by adjusting the surface functionalization of the nanoparticle, adding functionality to the nanomaterial. It has been shown that for BCPs infused with metal nanoparticles, there exists a minimum filling fraction within a subdomain such that the metal NPs can no longer be viewed as isolated but are coupled. The metal NP clusters begin to mimic bulk metals and generate collective plasmon resonances.

In one embodiment, GeTe was embedded in one domain of a BCP assembly and Au nanoparticles were embedded in another domain. Colloidal GeTe nanoparticles have been shown to exhibit phase change behavior. In this embodiment, phase switching was enhanced by the Au embedded domain, concentrating the optical field and assuring rapid heat diffusion on a picosecond scale with target switch times and thresholds as described above.

In order to properly formulate the design tool used herein, a new predictive model was developed and verified with a parametric study of building block material parameters. The new predictive model considered a system that contained semi-ordered arrays of non-metal nanoparticles-quantum dots (QDs) (for functionality) and metal nanoparticles (for field enhancement and energy dissipation). This two-entity complex of “meta-atoms” can be referred to as a “meta-molecule.” For this meta-molecule, both interband excitonic transitions (IBT) between the conduction and valence bands of the QDs and inter sub-band transitions (IST) within conduction band were considered.

In the presence of a strong optical field, strong coupling causes two effects. First, the character of non-metal nanoparticle exciton (meaning electron-hole distance and binding energy) can be changed optically. Second, the dynamic Stark effect alters the energy levels. In certain cases, the non-metal NPs are disordered and the coupling between them needs to be treated using the Hubbard model, which describes the behavior of correlated electrons in quantum systems. In the Hubbard model, the system is characterized by the coupling strength (V_{Q}) and the degree of disorder (δE). When the transition energy (ΔE) exceeds V_{Q}, Mott-Andersen localization takes place and material character changes from metal to dielectric. In addition to quantum considerations, the thermal transport equation must also be considered. When the mean free path of acoustic phonons exceeds the distance between the “meta molecules” one should consider the ballistic (shock wave) transfer of thermal energy. The difficulty in handling the aforementioned phenomena is that many of the relevant parameters—the degree of disorder, inter-nanoparticle coupling, exciton binding energies, energies of the IST, Rabi oscillation energies, phonon energies—are all within the same order of magnitude from 10 to 100 meV, and thus have to be handled self-consistently and non-perturbatively.

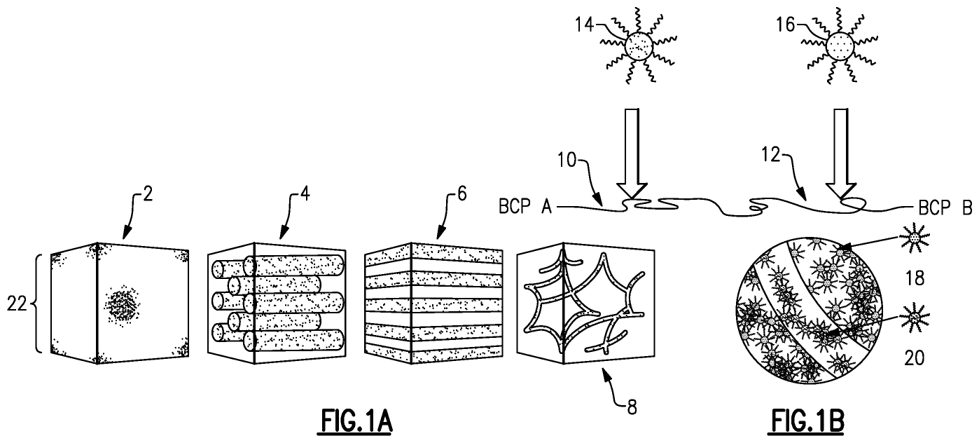

The model of the present disclosure combines in a self-consistent way solutions of the Maxwell equations within, and at the interfaces between, the domains of the NP embedded in the BCP building blocks. The electronic and thermal state of this combined disordered “meta-molecule” system is described by the Hubbard model and thermal transfer equations, respectively. The coupling (light-matter interaction) is described by density matrix equations. The available BCP unit cells provide different classes of material for light-matter interactions from isotropic (spheres), anisotropic (cylinders and lamellae), and chiral (gyroid), to a continuum of morphologies in-between (some BCP unit cells are shown in FIG. 1A).

Coulombic attraction between the electron and hole in each nanoparticle embedded in the BCP domain was treated together with the light matter interaction variationally so that field-induced changes in exciton radiuses were taken into account. BCPs self-assemble on nanometer length scales (10-100 nm unit cells) with subwavelength features ideal for a range of optical wavelengths, and these materials have shown promise for metamaterial fabrication. In general, BCPs consist of two or more chemically distinct and frequently immiscible monomer blocks that are covalently bonded together, See, e.g., FIG. 1A. Diblock copolymers consist of two such monomer blocks (A and B) that can microphase separate as a function of overall BCP composition, the degree of incompatibility between the A and B monomer segments, and the total degree of polymerization (i.e., molecular weight). The microphase separation leads to a variety of self-assembled morphologies including those shown in FIG. 1A.

Referring to FIG. 1A, possible nanoparticle embedded block co-polymer unit cells according to the principles of the present disclosure are shown. More specifically, several block co-polymer unit cells are shown including, but not limited to, spheres 2, cylinders 4, lamellae 6, and gyroid 8. The block co-polymer unit cells comprise at least two regions where one is a phase change nanoparticle region 20 and the other is a metal-doped polymer domain 18. In one embodiment, VO₂ 14 was a nanoparticle in a BCPA 10 domain, which acted as active media and Au 16 was a nanoparticle in a BCPB domain 12. The metal-doped domain 18 uses field enhancement at interstitial surfaces to magnify optical power within a phase change material thus lowering the optical threshold. In some cases, the metal-doped domain 18 also acts as a heat sink, increasing thermal dissipation thus reducing transition time. In certain embodiments, the thickness of the nanoparticle embedded block co-polymer unit cells is about 50 nm 22. FIG. 1B shows an enlarged region of the gyroid unit cell to demonstrate one example of the doped block co-polymer regions.

In certain embodiments, the optically induced phase change material can be used to realize all-optical switches which rapidly transition from a transparent insulator to a conducting metal with incident radiation. In some cases, the optically induced phase change material can be used as an optical limiter or a high-frequency optical modulator.

An optical limiter is an optical element placed in front of an optical detector which is transparent in normal conditions, but quickly switches to an opaque/reflective state upon irradiation of a laser source above a set threshold, thereby protecting the detector and/or operator from interrogating radiation. One embodiment used for this application contains GeTe or VO₂ and gold nanoparticles doped in alternating BCP domains to create a self-assembled and nanostructured material with a high spatial duty cycle, such that the gold doped domain was >90% of the unit cell with maximized surface area. Due to field enhancement from the high surface area, the optical field was concentrated inside the small GeTe/VO₂ embedded domains with tuned order/disorder, inducing an insulator to metal transition, and the bulk optical properties change dramatically from transmissive to reflective. Once the optical field was removed, the metal embedded domains provided a thermal short to allow for the dissipation of heat, quickly returning the phase change medium to its original dielectric state. In addition to optical limiter applications for laser hardening, there are potential applications to all-optical switches for optical computing and networking, and beam deflectors for rapid optical pointing.

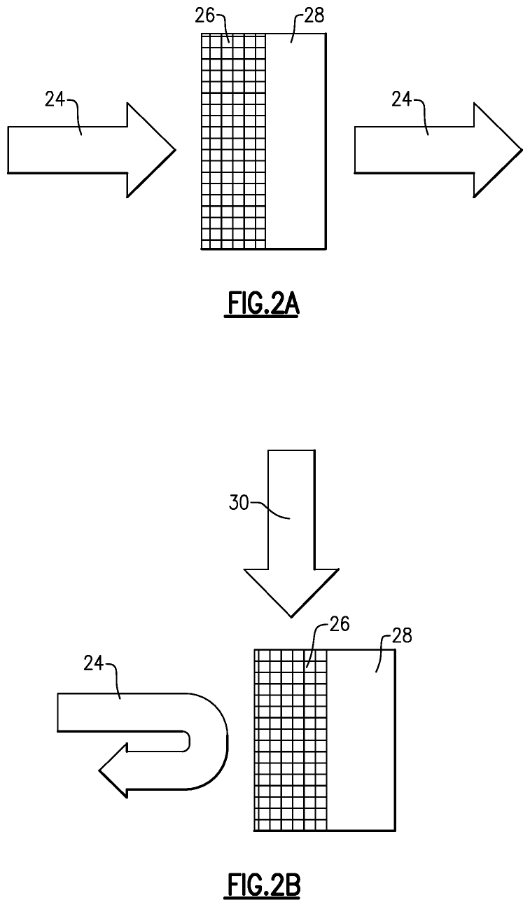

Referring to FIG. 2A, one embodiment of the optically induced phase change material of the present disclosure in an ON state in an all optical switch is shown. More specifically, signal light 24 passes through the optically induced phase change material 26 and glass 28 when the switch is ON. Referring to FIG. 2B, one embodiment of the optically induced phase change material of the present disclosure in an OFF state in an all optical switch is shown. More specifically, when the switch is OFF, gate light 30 causes the optically induced phase change material 26 to transition between a dielectric and metal state and the signal light 24 is reflected off the material 26. The wavelength of the gate light must fall in the absorption band of the phase change nanoparticles. The wavelength of the signal light must fall in the pass band when the phase change nanoparticles is in the insulator state. The thickness of the layers depends on the applications.

Some potential applications include low-cost optical limiters deposited on curved surfaces. Typically, optical materials used for optical limiters require foundry based deposition methods to apply to surfaces. Since this material is polymer based, it can be cast as a polymer film, and then applied to any curved surface. As a low-cost polymer optical limiter film, it can be applied to curved windows, lenses, domes, on rifle scopes, goggles, laser radar pods, and the like, to protect both optical detectors and human eyesight.

Some other potential applications include optical switches for optical communication applications. Since the material has a variable optically induced reflectivity, it can be used as a modulator to transfer encoded information onto a light source, or as a light controllable shutter for optical packet routing on a photonic chip.

While various embodiments of the present invention have been described in detail, it is apparent that various modifications and alterations of those embodiments will occur to and be readily apparent to those skilled in the art. However, it is to be expressly understood that such modifications and alterations are within the scope and spirit of the present invention, as set forth in the appended claims. Further, the invention(s) described herein is capable of other embodiments and of being practiced or of being carried out in various other related ways. In addition, it is to be understood that the phraseology and terminology used herein is for the purpose of description and should not be regarded as limiting. The use of “including,” “comprising,” or “having,” and variations thereof herein, is meant to encompass the items listed thereafter and equivalents thereof as well as additional items while only the terms “consisting of” and “consisting only of” are to be construed in a limitative sense.

The foregoing description of the embodiments of the present disclosure has been presented for the purposes of illustration and description. It is not intended to be exhaustive or to limit the present disclosure to the precise form disclosed. Many modifications and variations are possible in light of this disclosure. It is intended that the scope of the present disclosure be limited not by this detailed description, but rather by the claims appended hereto.

A number of implementations have been described. Nevertheless, it will be understood that various modifications may be made without departing from the scope of the disclosure. Although operations are depicted in the drawings in a particular order, this should not be understood as requiring that such operations be performed in the particular order shown or in sequential order, or that all illustrated operations be performed, to achieve desirable results.

While the principles of the disclosure have been described herein, it is to be understood by those skilled in the art that this description is made only by way of example and not as a limitation as to the scope of the disclosure. Other embodiments are contemplated within the scope of the present disclosure in addition to the exemplary embodiments shown and described herein. Modifications and substitutions by one of ordinary skill in the art are considered to be within the scope of the present disclosure.

What is claimed is:

1. An optically induced phase change material, comprising:
a block co-polymer structure as a meta-material scaffold having different classes of nanoparticles segregated and embedded in different domains, wherein the domains comprise:
a metal doped polymer domain; and
a phase change domain interface;
the metal doped polymer domain providing electric-field enhancement at an interface with the phase change domain, and providing a thermal heat sink for rapid thermal dissipation away from the phase change domain during an optical process.

2. The optically induced phase change material according to claim 1, wherein the metal doped polymer domain comprises a metal in any class of nanoparticles which allow for surface passivation with molecular ligands, including gold (Au), Silver (Ag), Copper (Cu), or Aluminum (Al).

3. The optically induced phase change material according to claim 1, wherein the phase change domain comprises a chalcogenide based phase change material, a transitional metal oxide, or a conventional optically active semiconductor.

4. The optically induced phase change material according to claim 3, wherein the chalcogenide based phase change material contains one or more chalcogen elements.

5. The optically induced phase change material according to claim 3, wherein the transitional metal oxide is VO₂.

6. The optically induced phase change material according to claim 3, wherein the conventional optically active semiconductor is CdSe.

7. The optically induced phase change material according to claim 1, wherein the optically induced phase change material has an optical threshold of about 10-100 μJ/cm² and a response time of about 10-100 ps.

8. The optically induced phase change material according to claim 1,
wherein the optical process is an optical limiter, an all-optical switch, an optical integrated circuit element, or a beam deflector.

9. A method of protecting an optical detector, comprising:
providing an optical limiter, the optical limiter comprising:
a block co-polymer structure as a meta-material scaffold having different classes of nanoparticles segregated and embedded in different domains, wherein the domains comprise:
a metal doped polymer domain; and
a phase change domain interface;
the metal doped polymer domain providing electric-field enhancement at an interface with the phase change domain, and providing a thermal heat sink for rapid thermal dissipation away from the phase change domain during an optical process;
the optical limiter being cast as a polymer film, and applied to a curved surface.

10. The method of protecting an optical detector according to claim 9, wherein the optical limiter switches to an opaque/reflective state upon irradiation by a laser source above a set threshold, thereby protecting the detector and/or an operator from interrogating radiation.

11. The method of protecting an optical detector according to claim 9, wherein the metal doped polymer domain comprises a metal in any class of nanoparticles which allow for surface passivation with molecular ligands, including gold (Au), Silver (Ag), Copper (Cu), or Aluminum (Al).

12. The method of protecting an optical detector according to claim 9, wherein the phase change domain comprises a chalcogenide based phase change material, a transitional metal oxide, or a conventional optically active semiconductor.

13. The method of protecting an optical detector according to claim 12, wherein the chalcogenide based phase change material contains one or more chalcogen elements.

14. The method of protecting an optical detector according to claim 12, wherein the transitional metal oxide is VO₂.

15. The method of protecting an optical detector according to claim 12, wherein the conventional optically active semiconductor is CdSe.

16. The method of protecting an optical detector according to claim 9, wherein the optically induced phase change material has an optical threshold of about 10-100 μJ/cm² and a response time of about 10-100 ps.

17. A method of optical switching, comprising:
providing an optical switch, wherein the optical switch, comprises:
a block co-polymer structure as a meta-material scaffold having different classes of nanoparticles segregated and embedded in different domains, wherein the domains comprise:
a metal doped polymer domain; and
a phase change domain interface;
the metal doped polymer domain providing electric-field enhancement at an interface with the phase change domain, and providing a thermal heat sink for rapid thermal dissipation away from the phase change domain during an optical process;
the meta-material having a variable optically induced reflectivity, to be used as a modulator to transfer encoded information onto a light source, or as a light controllable shutter for optical packet routing on a photonic chip.

18. The method of optical switching according to claim 17, wherein the optically induced phase change material has an optical threshold of about 10-100 μJ/cm² and a response time of about 10-100 ps.

19. The method of optical switching according to claim 17, wherein the metal doped polymer domain comprises a metal in any class of nanoparticles which allow for surface passivation with molecular ligands, including gold (Au), Silver (Ag), Copper (Cu), or Aluminum (Al).

20. The method of optical switching according to claim 17, wherein the phase change domain comprises a chalcogenide based phase change material, a transitional metal oxide, or a conventional optically active semiconductor.
